(19) United States
(12) Patent Application Publication
(10) Pub. No.: US 2025/0189604 A1
(43) Pub. Date: Jun. 12, 2025

(54) SENSOR DEVICES AND ASSOCIATED PRODUCTION METHODS

(71) Applicant: Infineon Technologies AG, Neubiberg (DE)

(72) Inventors: Patrick HANEKAMP, Laaber (DE); Andreas STRAßER, Regensburg (DE); Horst THEUSS, Wenzenbach (DE); Jürgen ZIMMER, Neubiberg (DE); Michael KIRSCH, Regensburg (DE); Christian GEISSLER, Teugn (DE)

(21) Appl. No.: 18/966,990

(22) Filed: Dec. 3, 2024

(30) Foreign Application Priority Data
Dec. 11, 2023 (DE) 102023212488.2

(51) Int. Cl. G01R 33/09

(52) U.S. Cl. CPC G01R 33/09

(57) ABSTRACT

A sensor device contains a magnetic field sensor chip having a front face, a rear face and a side surface connecting the front face and the rear face. The magnetic field sensor chip has a sensor element which is arranged on the front face and is configured to detect a magnetic field component running parallel to the front face. The magnetic field sensor chip furthermore has multiple first contact pads arranged on the front face, wherein all of the first contact pads arranged on the front face are arranged at an edge of the magnetic field sensor chip lying between the front face and the side surface.

### CROSS-REFERENCE TO RELATED APPLICATION

This application claims priority to Germany Patent Application No. 102023212488.2 filed on Dec. 11, 2023, the content of which is incorporated by reference herein in its entirety.

### TECHNICAL FIELD

The present disclosure relates to sensor devices and methods for producing such sensor devices.

### BACKGROUND

Magnetic field sensors may be used in various technical applications, for example in consumer products such as cell phones. Such applications generally require the sensors used therein to have small dimensions. Due to the increasing miniaturization of electronic components, increasingly high demands are being placed on the size and accuracy of magnetic field sensors. Manufacturers and developers of sensor devices are constantly striving to improve their products. It may be of particular interest to provide particularly small sensors which, despite their miniaturization, provide high measurement accuracy.

### SUMMARY

Various aspects relate to a sensor device. The sensor device includes a magnetic field sensor chip having a front face, a rear face and a side surface connecting the front face and the rear face. The magnetic field sensor chip includes a sensor element which is arranged on the front face and is configured to detect a magnetic field component running parallel to the front face. The magnetic field sensor chip furthermore includes multiple first contact pads arranged on the front face, wherein all of the first contact pads arranged on the front face are arranged at an edge of the magnetic field sensor chip lying between the front face and the side surface.

Various aspects relate to a sensor device. The sensor device includes a printed circuit board having a mounting surface and a magnetic field sensor chip in the form of a bare die having a front face, a rear face and a side surface connecting the front face and the rear face. The magnetic field sensor chip is mounted on the mounting surface of the printed circuit board and the side surface of the magnetic field sensor chip faces toward the mounting surface. The magnetic field sensor chip includes a sensor element which is arranged on the front face and is configured to detect a magnetic field component running parallel to the front face of the magnetic field sensor chip and perpendicular to the mounting surface of the printed circuit board.

Various aspects relate to a method for producing a sensor device. The method includes forming multiple sensor elements on a front face of a semiconductor wafer, wherein the sensor elements are configured to detect a magnetic field component running parallel to the front face. The method furthermore includes forming multiple first contact pads on the front face of the semiconductor wafer. The method furthermore includes separating the semiconductor wafer into a plurality of magnetic field sensor chips. Each magnetic field sensor chip includes a sensor element arranged on a front face of the magnetic field sensor chip and multiple first contact pads arranged on the front face, wherein all of the first contact pads arranged on the front face are arranged at an edge of the magnetic field sensor chip lying between the front face and a side surface of the magnetic field sensor chip.

### BRIEF DESCRIPTION OF THE DRAWINGS

Devices and methods according to the disclosure are explained in more detail hereinafter with reference to drawings. Identical reference signs here may denote identical or similar components. The features of the various examples illustrated may be combined with one another, provided that they are not mutually exclusive, and/or they may be selectively omitted if they are not described as absolutely necessary.

FIG. 1 shows a perspective view of a sensor device 100 according to the disclosure.

FIG. 2 shows a perspective view of a sensor device 200 according to the disclosure.

FIG. 3 shows a side view of a sensor device 300 according to the disclosure.

FIG. 4 shows a perspective view of a sensor device 400 according to the disclosure.

FIG. 5 shows a perspective view of a sensor device 500 according to the disclosure.

FIGS. 6A and 6B show steps for producing a sensor device 600 according to the disclosure.

FIGS. 7A to 7C show steps for producing a sensor device 700 according to the disclosure.

FIGS. 8A to 8C show steps for producing a sensor device 800 according to the disclosure.

FIG. 9 shows a side view of a sensor device 900 according to the disclosure.

FIG. 10 shows a flowchart of a method for producing a sensor device according to the disclosure.

### DETAILED DESCRIPTION

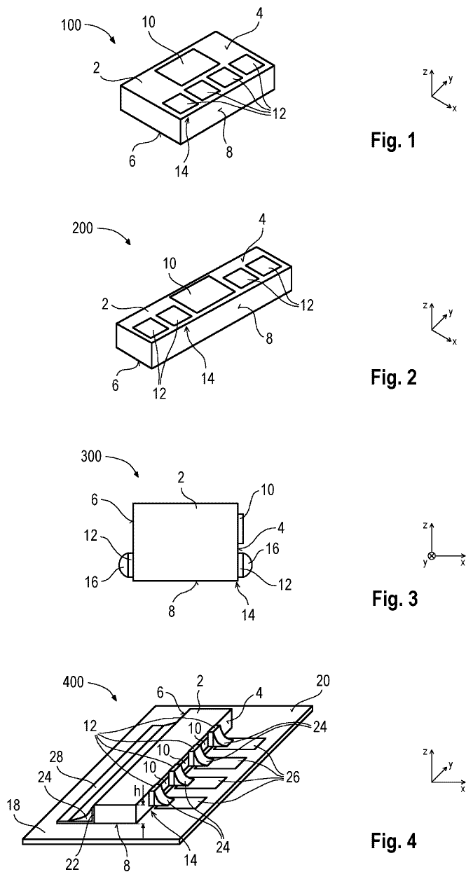

The sensor device 100 of FIG. 1 may have a magnetic field sensor chip 2 with a front face 4, a rear face 6 and a side surface 8 connecting the front face 4 and the rear face 6. The magnetic field sensor chip 2 may comprise a sensor element 10 arranged on the front face 4. The sensor element 10 may be configured to detect a magnetic field component running (e.g., extending) parallel to the front face 4. The magnetic field sensor chip 2 may furthermore have multiple contact pads 12 arranged on the front face 4. All of the contact pads 12 arranged on the front face 4 may be arranged at an edge 14 of the magnetic field sensor chip 2 lying between the front face 4 and the side surface 8.

The magnetic field sensor chip 2 may contain or be made of any semiconductor material, for example silicon. The magnetic field sensor chip 2 may be in particular a “bare die”, which need not necessarily be arranged in a housing, but can be processed further and used without such a housing. In this description, the terms “the” “chip”, “semiconductor die” and “semiconductor chip” may be used interchangeably.

In one example, the magnetic field sensor chip 2 may be a discrete semiconductor chip. A discrete semiconductor chip may correspond to a semiconductor component part that is configured to carry out an elementary electronic function and cannot be divided into separate components that are functional per se. In other words, a discrete semiconductor chip may correspond to a semiconductor component part which has only one basic function and not multiple complex functions, as can be the case, for example, with an integrated semiconductor circuit. In the present case, a basic function of the magnetic field sensor chip 2 may be seen in the detecting of the magnetic field present at the location of the sensor element 10 and an output of a measurement signal based thereon. In further examples, however, the magnetic field sensor chip 2 need not necessarily be a discrete semiconductor chip, e.g., the magnetic field sensor chip 2 may also be configured for further functions.

The magnetic field sensor chip 2 may have one or more sensor elements 10 arranged on the front face. In the example shown, a single sensor element 10 is shown for the sake of simplicity. The sensor element 10 may be configured to detect a magnetic field present at the location of the sensor element 10. More precisely, the sensor element 10 may be configured to detect a magnetic field component running parallel to the front face 4. The magnetic field sensor chip 2 may therefore be an “in-plane” magnetic field sensor. In this context, the sensor element 10 may be sensitive in the x direction, for example, e.g., may be configured to detect a magnetic field component in the x direction. Optionally, the sensor element 10 (or further sensor elements) may also be sensitive to further spatial directions. Measurement signals based on the detected magnetic field components may be output from the sensor device 100 to external components (not shown), for example via the contact pads 12.

In general, the magnetic field sensor chip 2 or its sensor element 10 does not have to be limited to a particular sensor technology. The sensor element 10 may be, for example, a Hall sensor element, a magnetoresistive sensor element, a vertical Hall sensor element or a Fluxgate sensor element. A magnetoresistive xMR sensor element may be an AMR (anisotropic magnetoresistive) sensor element, a GMR (giant magnetoresistive) sensor element, or a TMR (tunnel magnetoresistive) sensor element. In the example shown, the sensor element 10 may in particular contain or correspond to a TMR (tunnel magnetoresistive) sensor element, that is to say the magnetic field sensor chip 2 may correspond to an (in particular linear) TMR sensor chip.

The sensor element 10 may be implemented by way of example as a resistance bridge (not shown) with e.g., four resistors. The resistors may be, for example, TMR resistors, which can be arranged in the form of a bridge circuit, such as a Wheatstone bridge, for example. The sensor element 10 may be integrated into a circuit of the magnetic field sensor chip 2. In some examples, in addition and optionally, signal amplification, analog-to-digital conversion, digital signal processing and/or offset and temperature compensation may be carried out in such a circuit. In addition to the components of the sensor element 10, signal amplification components and/or analog-to-digital conversion components may or may not be considered as part of the sensor element 10.

The contact pads 12 may be configured to provide an electrical connection between external components (e.g., a printed circuit board) and electronic structures within the magnetic field sensor chip 2. In the example shown, the magnetic field sensor chip 2 may have four contact pads 12 arranged on its front face 4. However, this number is example, not limiting, and may differ in other examples. The contact pads 12 may be, for example, (in particular planar) solderable metal coatings, each of which may have a layer stack having one or more metal and/or metal alloy layers. In particular, such a metal stack may end with a solderable surface, e.g., the exposed surface of the contact pad 12 may be solderable. The solderable surface or the solderable layer stack may contain or be made of at least one of the following materials: NiSn, NiPAu, NiAu, NiPPdAu, NiMoP, AuSn, pure Sn, Cu (with surface protection), CuSn, or similar. The metal layers may be sputtered, or deposited by electroplating.

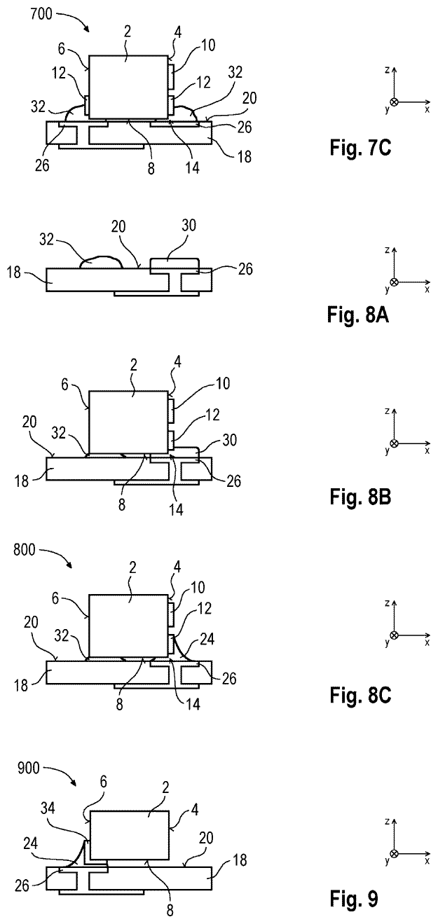

The contact pads 12 with solderable metal coatings may be used in particular to solder the sensor device 100 onto a printed circuit board, as shown by way of example in FIGS. 6A and 6B. In principle, the solderable metallizations may also be used if the sensor device 100 is attached to a printed circuit board via an adhesive, as shown by way of example in FIGS. 7A to 7C. In such a case, the contact pads 12 may in particular have a metal surface which is optimized for a reliable adhesive bond, such as AgPd for example.

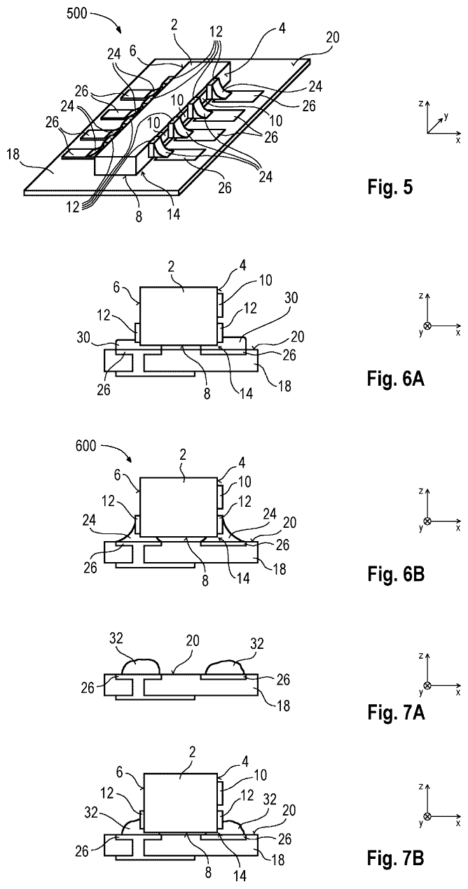

All of the contact pads 12 arranged on the front face 4 of the magnetic field sensor chip 2 may be arranged at the edge 14. Due to such an arrangement of the contact pads 12, the magnetic field sensor chip 2 may be mounted in a favorable manner on a printed circuit board, as shown and described by way of example in relation to FIGS. 4 and 5. In the example shown in FIG. 1, the contact pads 12 may be arranged substantially linearly along the edge 14. In particular, no further contact pads are arranged at the other three edges of the front face 4 or in the middle of the front face 4. In the illustrated case, the contact pads 12 may be arranged between the sensor element 10 and the edge 14. The sensor element 10 is thus not arranged at the edge 14, but may be spaced apart therefrom.

The magnetic field sensor chip 2 may optionally have one or more further contact pads arranged on its rear face 6, which further contact pads may not be visible in FIG. 1 due to the selected perspective. In one example, an arrangement of such second contact pads on the rear face 6 may be identical to an arrangement of the contact pads 12 on the front face 4. Such an arrangement of contact pads on the front and rear face of a magnetic field sensor chip is shown by way of example in FIG. 5. Alternatively, the rear face 6 of the magnetic field sensor chip 2 may not be structured and, for example, (in particular, completely) metallized. An arrangement of a magnetic field sensor chip with a metallized rear face on a printed circuit board is shown by way of example in FIG. 4.

The sensor device 200 of FIG. 2 may have some or all of the features of the sensor device 100 of FIG. 1. In the example shown, the sensor element 10 may be arranged at the edge 14 and between the contact pads 12. In comparison with the example of FIG. 1, a dimension of the magnetic field sensor chip 2 may be reduced in the x direction and enlarged in the y direction by such an arrangement of the sensor element 10.

The sensor device 300 of FIG. 3 may have some or all of the features of previously described sensor devices. The magnetic field sensor chip 2 may have contact pads 12 both on its front face 4 and on its rear face 6. Furthermore, the magnetic field sensor chip 2 may have solder caps 16 arranged on the contact pads 12. The solder caps 16 may optionally be arranged on a solderable surface of the respective contact pad 12. A solder cap 16 may contain or be made of at least one of the following materials: pure Sn, SnAg, SnAgCu, SnPb, in-based solders, or the like. The solder caps 16 may be produced, for example, using stencil printing, electroplating (both followed by a melting step) or a dip method.

The sensor device 400 of FIG. 4 may have some or all of the features of previously described sensor devices. The sensor device 400 may have a printed circuit board (or a PCB or a substrate) 18 with a mounting surface 20. The printed circuit board 18 may or may not be considered as part of the sensor device 400. A magnetic field sensor chip 2 may be mounted on the mounting surface 20, wherein the side surface 8 of the magnetic field sensor chip 2 may be facing toward the mounting surface 20. Multiple contact pads 12 may be arranged on the front face 4 of the magnetic field sensor chip 2 and electrically connected to the printed circuit board 18. In the example shown, the contact pads 12 may extend substantially over the total height of the front face 4 in the z direction. In a further example, the front face 4 measured in the z direction may be higher than the contact pads 12. In the illustrated case, the sensor elements 10 may be arranged between the contact pads 12. The rear face 6 of the magnetic field sensor chip 2 may be covered (in particular completely) with a metallization 22.

The contact pads 12 may be connected to the mounting surface 20 via a solder material 24. More specifically, the contact pads 12 may be mechanically and electrically connected to electrical contacts 26 of the printed circuit board 18 via the solder material 24. Such a connection may be made possible in particular in that all of the contact pads 12 arranged on the front face 4 are arranged at the edge 14 of the magnetic field sensor chip 2. By such an arrangement of the contact pads 12, a distance between the mounting surface 20 and all the contact pads 12 on the front face 4 may be reduced and the connection may thus be made possible at all. If, on the other hand, the contact pads 12 were spaced apart from the edge 14, a connection would not be possible or would at least be difficult.

In an analogous manner, the metallization 22 on the rear face 6 of the magnetic field sensor chip 2 may be connected to the mounting surface 20 via a solder material 24. The metallization 22 may be mechanically and (optionally) electrically connected to a metal layer 28 of the printed circuit board 18, for example, via the solder material 24. The metal layer 28 may be, for example, an electrical contact of the printed circuit board 18.

The contact pads 12 arranged on the front face 4 may in principle be sufficient to provide an electrical and mechanical connection of the magnetic field sensor chip 2 to the printed circuit board 18. However, in the case of a soldering process, a one-sided connection carries the risk of a “tombstone” effect, which may lead to the magnetic field sensor chip 2 being inclined or upright. An additional connection between the rear face 6 and the printed circuit board 18 may avoid or at least reduce the risk of a “tombstone” effect.

As described in relation to the example of FIG. 1, the magnetic field sensor chip 2 may be an in-plane magnetic field sensor, e.g., a sensor element 10 of the magnetic field sensor chip 2 may be configured to detect a magnetic field component running parallel to the front face 4. Since the magnetic field sensor chip 2 in the example of FIG. 4 with its side surface 8 is mounted on the mounting surface 20 of the printed circuit board 18, the front face 4 may be substantially perpendicular to the mounting surface 20. Therefore, the sensor element 10 may be configured to detect a magnetic field component running perpendicular to the mounting surface 20. In other words, by rotating the magnetic field sensor chip 2 with its (intrinsic) in-plane functionality by 90 degrees (or as a result of its vertical orientation), the functionality of an out-of-plane magnetic field sensor may be provided.

By selecting a chip layout with a high aspect ratio, a particularly low height h of the magnetic field sensor chip 2 in the z direction may be provided in the example of FIG. 4. The height h may be reduced to a minimum value of approximately 50 μm micrometers. The height h may therefore be, for example, less than approximately 100 μm or less than approximately 90 μm or less than approximately 80 μm or less than approximately 70 μm or less than approximately 60 μm or less than approximately 55 μm. Minimum dimensions of the magnetic field sensor chip 2 in the x direction and the y direction may be approximately 50 μm and approximately 400 μm respectively. A minimum base area of the magnetic field sensor chip 2 may therefore be approximately 50 μm×400 μm.

According to the remarks above, the functionality of an out-of-plane magnetic field sensor with a particularly low overall height may be provided by sensor devices according to the disclosure. Out-of-plane magnetic field sensors may frequently be used in consumer products such as cell phones. Such applications regularly require the sensors used therein to have particularly small dimensions. The sensor devices described herein may thus be used in particular in the products.

Conventional sensor devices with out-of-plane functionality may have increased dimensions compared to the sensor devices according to the disclosure, since they use an additional chip housing and/or an additional magnetic flux concentrator to change a direction of the magnetic field component to be detected. By contrast, the sensor devices according to the disclosure which are described herein do not require a magnetic flux concentrator or an additional chip housing to provide out-of-plane functionality.

The sensor device 500 of FIG. 5 may have some or all of the features of previously described sensor devices. In addition to the contact pads 12 on the front face 4, the magnetic field sensor chip 2 may comprise multiple further contact pads 12 arranged on its rear face 6. In the example shown, an arrangement of these further contact pads 12 on the rear face 6 may be identical to an arrangement of the contact pads 12 on the front face 4. By such an arrangement of the contact pads 12, symmetrical melting and wetting behavior may be achieved during a soldering process. The contact pads 12 of the magnetic field sensor chip 2 may be mechanically and electrically connected to electrical contacts 26 of the printed circuit board 18 via a solder material 24.

FIGS. 6A and 6B show steps for producing a sensor device 600 according to the disclosure. More specifically, a side view of a mounting of a magnetic field sensor chip 2 on a printed circuit board 18 is illustrated. In the example shown, the magnetic field sensor chip 2 may have contact pads 12 both on its front face 4 and on its rear face 6.

In a first step (not shown), a solder paste (or soft solder) 30 may be selectively arranged on the mounting surface 20 of the printed circuit board 18, for example by a printing process. The solder paste 30 may be deposited in particular on electrical contacts 26 of the printed circuit board 18.

In FIG. 6A, the magnetic field sensor chip 2 may be arranged with its side surface 8 on the mounting surface 20 of the printed circuit board 18, for example by a pick-and-place process. The contact pads 12 may be aligned with the selectively deposited solder paste 30. Due to their arrangement at the edge 14 of the magnetic field sensor chip 2, the contact pads 12 may contact the solder paste 30.

In FIG. 6B, the solder paste 30 may transition into a molten state during a reflow process and form permanent solder joints 24 of the sensor device 600 after cooling.

FIGS. 7A to 7C show steps for producing a sensor device 700 according to the disclosure. More specifically, a side view of a mounting of a magnetic field sensor chip 2 on a printed circuit board 18 is illustrated. In the example shown, the magnetic field sensor chip 2 may have contact pads 12 both on its front face 4 and on its rear face 6.

In FIG. 7A, an (in particular not yet cured) adhesive 32 may be selectively deposited on the printed circuit board 18, for example by a printing process and/or a dispensing process. The adhesive 32 may be deposited in particular on electrical contacts 26 of the printed circuit board 18. Depending on the application, the adhesive 32 may or may not be electrically conductive. For example, an electrically conductive adhesive 32 may be a silver-filled epoxy.

In FIG. 7B, the magnetic field sensor chip 2 may be arranged with its side surface 8 on the mounting surface 20 of the printed circuit board 18, for example by a pick-and-place process. The contact pads 12 may be aligned with the selectively deposited adhesive 32. Due to their arrangement at the edge 14 of the magnetic field sensor chip 2, the contact pads 12 may contact the adhesive 32.

In FIG. 7C, the adhesive 32 may cure in a curing process. The contact pads 12 arranged on the front face 4 and the rear face 6 of the magnetic field sensor chip 2 may thus be permanently mechanically connected to the printed circuit board 18 via the cured adhesive 32. In the case of an electrically conductive adhesive 32, an electrical connection may be additionally provided.

FIGS. 8A to 8C show steps for producing a sensor device 800 according to the disclosure. More specifically, a side view of a mounting of a magnetic field sensor chip 2 on a printed circuit board 18 is illustrated. In the example shown, the magnetic field sensor chip 2 may have contact pads 12 only on its front face 4.

In FIG. 8A, an (in particular not yet cured) adhesive 32 and a solder paste 30 may be selectively deposited on the printed circuit board 18. The solder paste 30 may be arranged in particular on electrical contacts 26 of the printed circuit board 18. As an alternative to the solder paste 30, an electrically conductive adhesive may be used in another example. The adhesive 32 may be in particular a non-electrically conductive adhesive, to reduce the risk of short circuits.

In FIG. 8B, the magnetic field sensor chip 2 may be arranged with its side surface 8 on the mounting surface 20 of the printed circuit board 18, for example by a pick-and-place process. The contact pads 12 may be aligned with the selectively deposited solder paste 30. In addition, the side surface 8 of the magnetic field sensor chip 2 may be aligned with the adhesive 32.

In FIG. 8C, the adhesive 32 may cure in a curing process and form permanent mechanical connections between the side surface 8 of the magnetic field sensor chip 2 and the printed circuit board 18. In particular, the risk of a “tombstone” effect may be avoided or at least reduced as a result. Furthermore, the solder paste 30 may transition into a molten state during a reflow process and form permanent solder joints 24 of the sensor device 800 after cooling. If an electrically conductive adhesive is used as an alternative to the solder paste 30, only a curing process may be carried out in FIG. 8C, but no additional reflow process.

The sensor device 900 of FIG. 9 may have some or all of the features of previously described sensor devices. In the example shown, sensor elements and contact pads arranged on the front face 4 of the magnetic field sensor chip 2 are not shown for the sake of simplicity. The magnetic field sensor chip 2 may have a metallization 34, which may extend at least partially over the rear face 6 and the side surface 8 and the edge, lying between them, of the magnetic field sensor chip 2. The metallization 34 extending over the edge may increase the reliability of a solder process carried out.

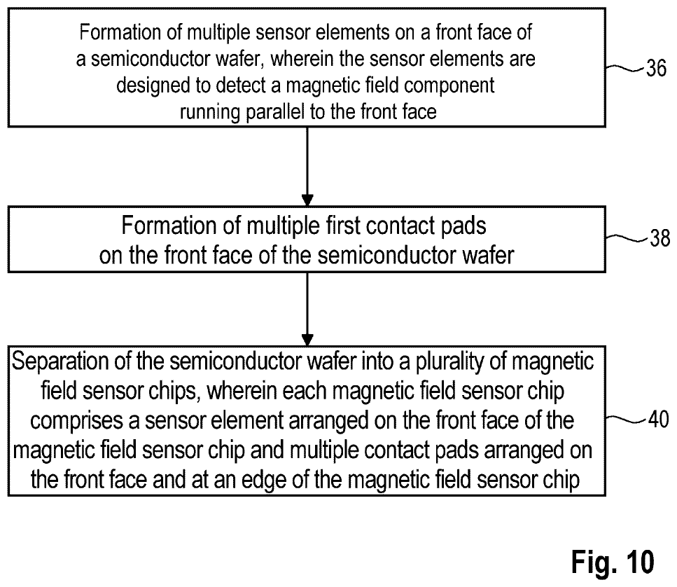

FIG. 10 shows a flowchart of a method for producing sensor devices according to the disclosure. The method of FIG. 10 is described in a general form to qualitatively specify aspects of the present disclosure. The method may comprise further aspects. For example, the method may be expanded to include each of the aspects described herein in conjunction with other examples. In particular, the method for producing the previously described sensor devices according to the disclosure may be used.

In a step 36, multiple sensor elements (e.g., plurality of sensor elements) may be formed on a front face of a semiconductor wafer. The sensor elements may be configured to detect a magnetic field component running parallel to the front face. In a further step 38, multiple first contact pads (e.g., a plurality of first contact pads) may be formed on the front face of the semiconductor wafer. In a further step 40, the semiconductor wafer may be separated into a plurality of magnetic field sensor chips. Each magnetic field sensor chip may comprise a sensor element, of the multiple sensor elements, arranged on a front face of the magnetic field sensor chip and multiple first contact pads, of the plurality of first contact pads, arranged on the front face. All of the multiple first contact pads arranged on the front face of the magnetic field sensor chip may be arranged at an edge of the magnetic field sensor chip lying between the front face of the magnetic field sensor chip and a side surface of the magnetic field sensor chip. Multiple second contact pads (e.g., a plurality of second contact pads) may be formed on the rear face of the semiconductor wafer. Each magnetic field sensor chip may comprise multiple second contact pads, of the plurality of second contact pads, arranged on a rear face of the magnetic field sensor chip, as described above.

For example, the method may be expanded by one or more of the steps described in FIGS. 6 to 8. In a further step, for example, the magnetic field sensor chip may therefore be mounted on a mounting surface of a printed circuit board. In yet a further step, the first contact pads may be electrically connected to the printed circuit board.

ASPECTS Hereinafter, sensor devices according to the disclosure and associated production methods are described using aspects.

Aspect 1 is a sensor device comprising: a magnetic field sensor chip having a front face, a rear face and a side surface connecting the front face and the rear face, wherein the magnetic field sensor chip comprises: a sensor element which is arranged on the front face and is configured to detect a magnetic field component running parallel to the front face, and multiple first contact pads arranged on the front face, wherein all of the first contact pads arranged on the front face are arranged at an edge of the magnetic field sensor chip lying between the front face and the side surface.

Aspect 2 is a sensor device according to Aspect 1, wherein the magnetic field sensor chip is a bare die.

Aspect 3 is a sensor device according to Aspect 1 or 2, wherein the first contact pads are arranged linearly along the edge.

Aspect 4 is a sensor device according to one of the preceding aspects, wherein the sensor element is arranged at the edge and between the first contact pads.

Aspect 5 is a sensor device according to one of Aspects 1 to 3, wherein the first contact pads are arranged between the sensor element and the edge.

Aspect 6 is a sensor device according to one of the preceding aspects, wherein the magnetic field sensor chip comprises multiple second contact pads arranged on the rear face.

Aspect 7 is a sensor device according to Aspect 6, wherein an arrangement of the second contact pads on the rear face is identical to an arrangement of the first contact pads on the front face.

Aspect 8 is a sensor device according to one of Aspects 1 to 5, wherein the rear face of the magnetic field sensor chip is metallized.

Aspect 9 is a sensor device according to one of the preceding aspects, wherein the sensor element is a magnetoresistive sensor element.

Aspect 10 is a sensor device according to one of the preceding aspects, furthermore comprising: a printed circuit board, wherein: the magnetic field sensor chip is mounted on a mounting surface of the printed circuit board and the side surface of the magnetic field sensor chip faces toward the mounting surface, and the first contact pads are electrically connected to the printed circuit board.

Aspect 11 is a sensor device according to Aspect 10, wherein the sensor element is configured to detect a magnetic field component running perpendicular to the mounting surface.

Aspect 12 is a sensor device according to Aspect 10 or 11, wherein the first contact pads and the second contact pads are connected to the mounting surface via a solder material.

Aspect 13 is a sensor device according to Aspect 10 or 11, wherein the first contact pads and the second contact pads are connected to the mounting surface via an electrically conductive adhesive.

Aspect 14 is a sensor device according to Aspect 10 or 11, wherein the first contact pads are connected to the mounting surface via a solder material and the side surface of the magnetic field sensor chip is connected to the mounting surface via a non-electrically conductive adhesive.

Aspect 15 is a sensor device according to one of the preceding aspects, wherein the sensor device does not have a magnetic flux concentrator, which is configured to change a direction of the magnetic field component detected by the sensor element.

Aspect 16 is a sensor device, comprising: a printed circuit board having a mounting surface; and a magnetic field sensor chip in the form of a bare die having a front face, a rear face and a side surface connecting the front face and the rear face, wherein the magnetic field sensor chip is mounted on the mounting surface of the printed circuit board and the side surface of the magnetic field sensor chip faces toward the mounting surface, wherein the magnetic field sensor chip comprises a sensor element which is arranged on the front face and is configured to detect a magnetic field component running parallel to the front face of the magnetic field sensor chip and perpendicular to the mounting surface of the printed circuit board.

Aspect 17 is a sensor device according to Aspect 16, wherein the magnetic field sensor chip comprises multiple first contact pads arranged on the front face, wherein all of the first contact pads arranged on the front face are arranged at an edge of the magnetic field sensor chip lying between the front face and the side surface.

Aspect 18 is a method for producing a sensor device, wherein the method comprises: forming multiple sensor elements on a front face of a semiconductor wafer, wherein the sensor elements are configured to detect a magnetic field component running parallel to the front face; forming a plurality of first contact pads on the front face of the semiconductor wafer; separating the semiconductor wafer into a plurality of magnetic field sensor chips, wherein each magnetic field sensor chip comprises: a sensor element, of the multiple sensor elements, arranged on a front face of the magnetic field sensor chip, and multiple first contact pads, of the plurality of first contact pads, arranged on the front face, wherein all of the first contact pads arranged on the front face are arranged at an edge of the magnetic field sensor chip lying between the front face and a side surface of the magnetic field sensor chip.

Aspect 19 is a method according to Aspect 18, furthermore comprising: mounting the magnetic field sensor chip on a mounting surface of a printed circuit board, wherein the side surface of the magnetic field sensor chip faces toward the mounting surface; and electrically connecting the first contact pads to the printed circuit board.

Although specific implementations are illustrated and described herein, it is obvious to the average skilled person that a plurality of alternative and/or equivalent implementations may replace the specific implementations shown and described, without departing from the scope of the present disclosure. This application is intended to cover all adaptations or variations of the specific implementations discussed herein. Therefore, the intention is for this disclosure to be restricted only by the claims and the equivalents thereof.

1. A sensor device, comprising:
a magnetic field sensor chip having a front face, a rear face, and a side surface connecting the front face and the rear face, wherein the magnetic field sensor chip comprises:
a sensor element arranged on the front face and is configured to detect a magnetic field component extending parallel to the front face, and
multiple first contact pads arranged on the front face, wherein all of the multiple first contact pads arranged on the front face are arranged at an edge of the magnetic field sensor chip lying between the front face and the side surface.

2. The sensor device as claimed in claim 1, wherein the magnetic field sensor chip is a bare die.

3. The sensor device as claimed in claim 1, wherein the multiple first contact pads are arranged linearly along the edge.

4. The sensor device as claimed in claim 1, wherein the sensor element is arranged at the edge and between the multiple first contact pads.

5. The sensor device as claimed in claim 1, wherein the multiple first contact pads are arranged between the sensor element and the edge.

6. The sensor device as claimed in claim 1, wherein the magnetic field sensor chip comprises multiple second contact pads arranged on the rear face.

7. The sensor device as claimed in claim 6, wherein an arrangement of the multiple second contact pads on the rear face is identical to an arrangement of the multiple first contact pads on the front face.

8. The sensor device as claimed in claim 1, wherein the rear face of the magnetic field sensor chip is metallized.

9. The sensor device as claimed in claim 1, wherein the sensor element is a magnetoresistive sensor element.

10. The sensor device as claimed in claim 1, further comprising:
a printed circuit board, wherein:
the magnetic field sensor chip is mounted on a mounting surface of the printed circuit board and the side surface of the magnetic field sensor chip faces toward the mounting surface, and
the multiple first contact pads are electrically connected to the printed circuit board.

11. The sensor device as claimed in claim 10, wherein the sensor element is configured to detect a magnetic field component extending perpendicular to the mounting surface.

12. The sensor device as claimed in claim 10, wherein the multiple first contact pads and the multiple second contact pads are connected to the mounting surface via a solder material.

13. The sensor device as claimed in claim 10, wherein the multiple first contact pads and the multiple second contact pads are connected to the mounting surface via an electrically conductive adhesive.

14. The sensor device as claimed in claim 10, wherein the multiple first contact pads are connected to the mounting surface via a solder material, and
wherein the side surface of the magnetic field sensor chip is connected to the mounting surface via a non-electrically conductive adhesive.

15. The sensor device as claimed in claim 1, wherein the sensor device does not have a magnetic flux concentrator, which is configured to change a direction of the magnetic field component detected by the sensor element.

16. A sensor device, comprising:
a printed circuit board having a mounting surface; and
a magnetic field sensor chip in the form of a bare die having a front face, a rear face, and a side surface connecting the front face and the rear face,
wherein the magnetic field sensor chip is mounted on the mounting surface of the printed circuit board, and
wherein the side surface of the magnetic field sensor chip faces toward the mounting surface, and
wherein the magnetic field sensor chip comprises a sensor element which is arranged on the front face and is configured to detect a magnetic field component extending parallel to the front face of the magnetic field sensor chip and extending perpendicular to the mounting surface of the printed circuit board.

17. The sensor device as claimed in claim 16, wherein the magnetic field sensor chip comprises multiple first contact pads arranged on the front face, and
wherein all of the multiple first contact pads arranged on the front face are arranged at an edge of the magnetic field sensor chip lying between the front face and the side surface.

18. A method for producing a sensor device, wherein the method comprises:
forming multiple sensor elements on a front face of a semiconductor wafer, wherein the multiple sensor elements are configured to detect a magnetic field component extending parallel to the front face;
forming a plurality of first contact pads on the front face of the semiconductor wafer;
separating the semiconductor wafer into a plurality of magnetic field sensor chips, wherein each magnetic field sensor chip comprises:
a sensor element, of the multiple sensor elements, arranged on a front face of the magnetic field sensor chip, and
multiple first contact pads, of the plurality of first contact pads, arranged on the front face, wherein all of the multiple first contact pads arranged on the front face of the magnetic field sensor chip are arranged at an edge of the magnetic field sensor chip lying between the front face of the magnetic field sensor chip and a side surface of the magnetic field sensor chip.

19. The method as claimed in claim 18, further comprising:
mounting the magnetic field sensor chip on a mounting surface of a printed circuit board, wherein the side surface of the magnetic field sensor chip faces toward the mounting surface; and
electrically connecting the multiple first contact pads to the printed circuit board.
